(19) United States
(12) Patent Application Publication
(10) Pub. No.: US 2012/0103382 A1
(43) Pub. Date: May 3, 2012

(54) THERMOELECTRIC GENERATION APPARATUS

(76) Inventors: Cheng-Ting HSU, Taipei City (TW); Da-Jang Yao, Hsinchu City (TW); Chien-Neng Liao, Taichung City (TW)

(21) Appl. No.: 13/093,521

(22) Filed: Apr. 25, 2011

(30) Foreign Application Priority Data
Nov. 3, 2010 (TW) 099137753

(51) Int. Cl. H01L 35/02

(52) U.S. Cl. 136/242

(57) ABSTRACT

A thermoelectric generation apparatus connected with a heat generation element includes a spreader and at least one thermoelectric generator. The spreader has two opposite surfaces with one surface attached to the thermoelectric generator and another surface attached to the heat generation element. The thermoelectric generator converts thermal energy into electric energy to be output. Through the spreader, thermal energy of the heat generation element can be conducted to be evenly distributed on the surface of the spreader to improve undesirable heat generation efficiency of the thermoelectric generator caused by uneven temperature distributed on the surface of the heat generation element.

### FIELD OF THE INVENTION

The present invention relates to an energy conversion apparatus and particularly to an apparatus to convert thermal energy to electric energy.

### BACKGROUND OF THE INVENTION

With gradual decrease of oil reserves in the world, oil price increases constantly. Energy saving, carbon reduction, and energy resource reuse have become an important trend that cannot be ignored. Thermoelectric generation techniques related to waste heat have been developed and used in apparatus or systems that generate exhaust gases with a great amount of heat. In the past, the waste heat generated in an exhaust pipe was directly discharged into the air and resulted in waste of the thermal energy and also caused global temperature increasing. Thermoelectric generation apparatus can effectively resolve those two problems by converting the waste heat into electrical energy and lowering the temperature of the discharged waste heat simultaneously, thus is more eco-friendly.

For instance, R.O.C. publication No. 201019515 entitled “Thermoelectric generation system” includes at least one electric generation element and a heat dissipation device. Each of the electric generation elements has a heat absorption side, a thermoelectric alloy material and an electric power output end. The heat absorption side is directly in contact with a heat source and conducts the heat to the thermoelectric alloy material to convert the heat into electric current.

However, when the temperature of the heat source drops significantly, the thermoelectric generation efficiency of the electric generation element located at a position with the lower temperature also decreases. For example, in an exhaust pipe, a cooling effect is formed after exhaust gas with high temperature has entered and temperature drops significantly from the input end to the output end of the exhaust pipe. Hence thermoelectric generation efficiency gradually decreases at the position closer to the distal end of the exhaust pipe due to the lower temperature.

### SUMMARY OF THE INVENTION

The primary object of the present invention is to solve the problem of the conventional thermoelectric generation system that has lower thermoelectric generation efficiency of the electric generation element at a lower temperature location when temperature is unevenly distributed on the heat generation element where thermal energy is captured to be converted to electric energy.

To achieve the foregoing object, the present invention provides a thermoelectric generation apparatus connected to a heat generation element. The thermoelectric generation apparatus includes a spreader which is a conductive layer to uniform temperature distribution and at least one thermoelectric generator. The spreader is attached to the heat generation element to conduct heat of the heat generation element to be evenly distributed on the surface of the spreader. The spreader also increases the heated temperature of the thermoelectric generator originally attached to the lower temperature position of the heat generation element to improve thermoelectric generation efficiency of the thermoelectric generator. The thermoelectric generator attached to the spreader converts the received thermal energy into electric energy to be output.

Thus, by attaching the spreader to the heat generation element, thermal energy of the heat generation element can be conducted and evenly distributed on the surface of the spreader. As a result, the thermoelectric generator originally attached to the lower temperature position of the heat generation element is now attached to the spreader, heated temperature of the thermoelectric generator increases and thermoelectric generation efficiency thereof improves.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is a perspective view of an embodiment of the invention.

FIG. 1B is a sectional view taken on line A-A in FIG. 1.

FIG. 2 is a sectional view of an embodiment including a thermal interface material according to the invention.

### DETAILED DESCRIPTION OF THE PREFERRED EMBODIMENTS

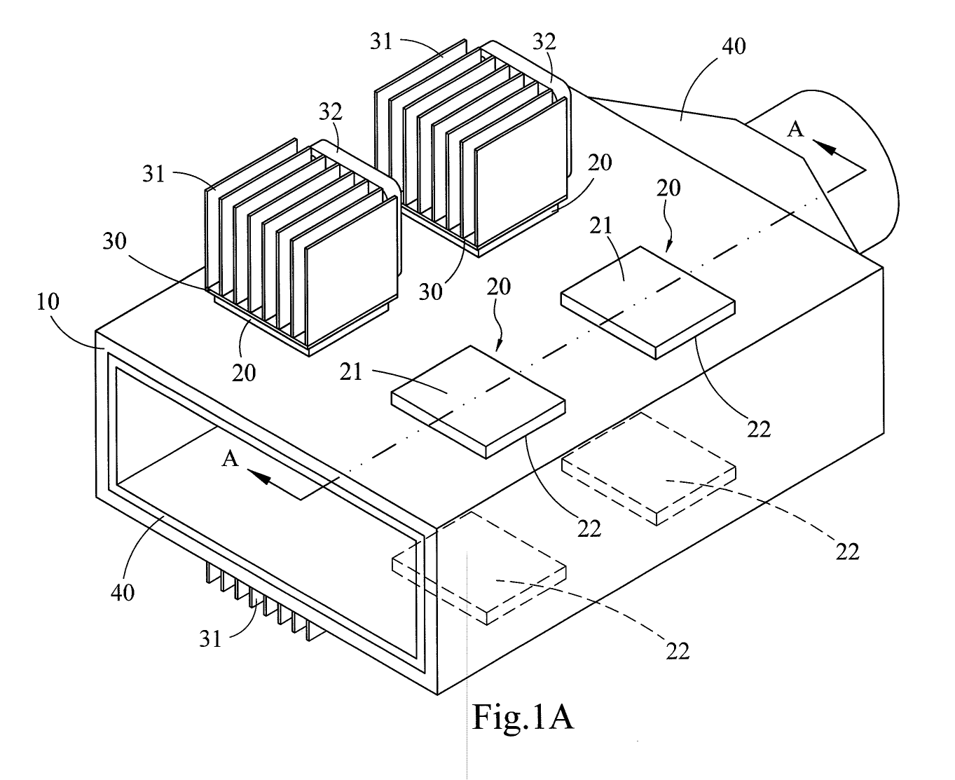

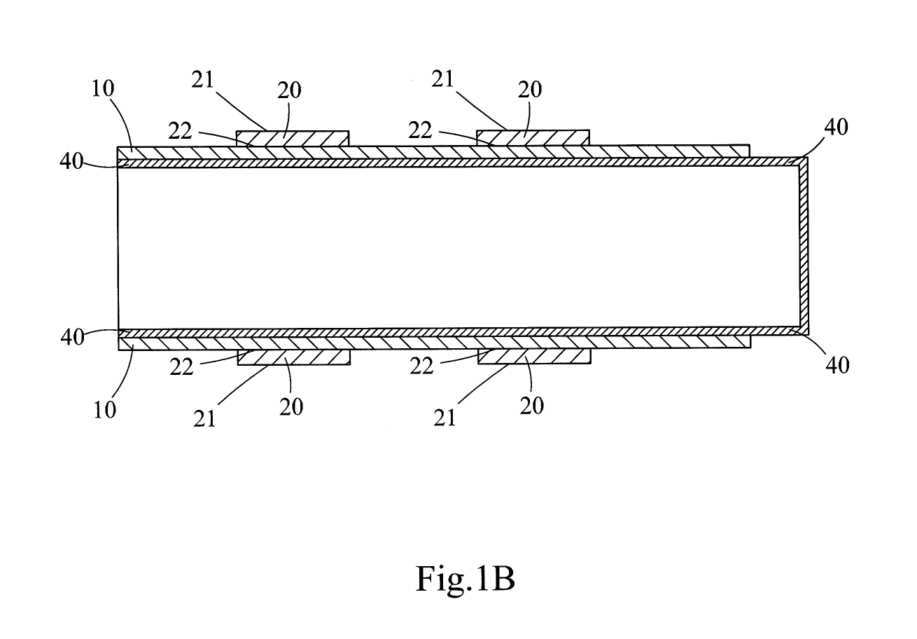

Refer to FIGS. 1A and 1B for an embodiment of the invention. The present invention aims to provide a thermoelectric generation apparatus which comprises a spreader 10 and at least one thermoelectric generator 20.

The spreader 10 is attached to a heat generation element 40 which is an exhaust pipe in this embodiment. The spreader 10 is made of a metal material selected from the group consisting of silver, copper, aluminum, iron, gold and combinations thereof. In general, silver is the best heat conduction material, but is more expensive, hence a cheaper material, copper, which also has desirable heat conduction effect, is selected to fabricate the spreader 10.

The thermoelectric generator 20 has a heat dissipation device 30 located thereon. The thermoelectric generator 20 receives thermal energy and converts the thermal energy into electric energy to be output. The thermoelectric generator 20 has a heating surface 22 and a cooling surface 21 on the opposite side. The heating surface 22 is attached to the spreader 10 to absorb heat thereof. The heat dissipation device 30 can be an air cooling device or water cooling device. In this embodiment, an air cooling device is used as an example. The heat dissipation device 30 is a heat sink and has a plurality of heat sink fins 31 and an air fan 32 to facilitate cooling. In the event that the thermoelectric generation apparatus is attached to an exhaust pipe of a vehicle, airflow generated by the vehicle during moving can substitute the air fan 32 to perform cooling of the heat dissipation device 30 without installing the air fan 32. The heat dissipation device 30 is attached to the cooling surface 21 to aid cooling of the cooling surface 21, reduce the temperature of the cooling surface 21, and increase temperature difference between the cooling surface 21 and heating surface 22 to improve conversion efficiency of the thermoelectric generator 20.

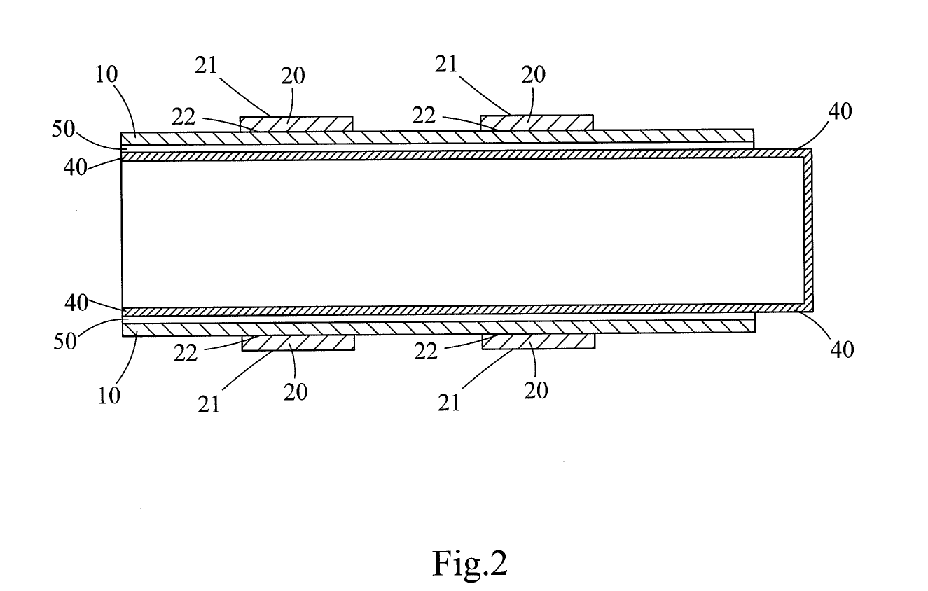

Referring to FIG. 2, as the spreader 10 and heat generation element 40 usually are respectively made of a metal material in a solid state, a gap is easily formed between the junction surfaces thereof due to technical problems of joining. As the air in the gap is a poor heat conduction medium, the gap is filled with a thermal interface material 50 to reduce effect of contacting thermal resistance and also evenly distribute heat of the heat generation element 40 on the surface of the spreader 10 to further improve heat conduction efficacy. In general, the thermal interface material 50 can be thermal grease or silicone oil.

In this embodiment, the thermoelectric generation apparatus is applied to the heat generation element 40 and includes a plurality of thermoelectric generators 20. Due to heat absorption of the multiple thermoelectric generator 20, the surface temperature of the heat generation element 40 decreases significantly, even at greater extent at locations remote from the heating source. By attaching the spreader 10 to the heat generation element 40 and with the aid of the thermal interface material 50, heat from the heat generation element 40 can be quickly conducted to the spreader 10 to be evenly distributed on the surface thereof. Therefore, the thermoelectric generators 20 originally attached to the heat generation element 40 are now attached to the spreader 10, more thermoelectric generators 20 can be adopted remote from the heating source and more heating surfaces 22 are provided to receive the thermal energy. As a result, temperature difference between the heating surface 22 and cooling surface 21 of the thermoelectric generator 20 increases, thus thermoelectric generation efficiency of the thermoelectric generator 20 improves.

As a conclusion, through the spreader 10, the thermoelectric generation efficiency of at least one thermoelectric generator 20 installed at a lower temperature position of the heat generation element 40 improves to increase utilization of converting the waste heat into the electric power, not only impact of the waste heat to global environment is reduced, it is also more eco-friendly in terms of energy resource reuse. Energy saving and carbon reduction effect can be accomplished. It is especially desirable to be adopted on vehicles or plants that discharge a great amount of heated exhaust gases.

While the invention has been described by means of specific embodiments, numerous modifications and variations could be made thereto by those skilled in the art without departing from the scope and spirit of the invention set forth in the claims.

In summation of the above description, the present invention provides a significant improvement over the conventional techniques and complies with the patent application requirements, and is submitted for review and granting of the commensurate patent rights.

What is claimed is:

1. A thermoelectric generation apparatus connected with a heat generation element, comprising:
a spreader attached to the heat generation element to allow thermal energy of the heat generation element to be evenly distributed on the surface of the spreader; and
at least one thermoelectric generator attached to the spreader to convert the received thermal energy to electric energy to be output.

2. The thermoelectric generation apparatus of claim 1, wherein the thermoelectric generator includes a heat dissipation device, a cooling surface and a heating surface opposite to the cooling surface, the heating surface being attached to the spreader to absorb the heat thereof, the heat dissipation device being attached to the cooling surface to aid cooling of the cooling surface.

3. The thermoelectric generation apparatus of claim 2, wherein the heat dissipation device is a heat sink.

4. The thermoelectric generation apparatus of claim 3, wherein the heat sink includes a plurality of heat sink fins.

5. The thermoelectric generation apparatus of claim 3, wherein the heat sink includes an air fan to aid cooling thereof.

6. The thermoelectric generation apparatus of claim 1, wherein the spreader is made of a metal material.

7. The thermoelectric generation apparatus of claim 6, wherein the metal material is selected from the group consisting of silver, copper, aluminum, iron, gold and combinations thereof.

8. The thermoelectric generation apparatus of claim 1, wherein the heat generation element is an exhaust pipe, the spreader covering the surface of the exhaust pipe.

9. The thermoelectric generation apparatus of claim 1, wherein the heat generation element and the spreader are interposed by a thermal interface material.
